(19) United States
(12) Patent Application Publication
(10) Pub. No.: US 2022/0224293 A1
(43) Pub. Date: Jul. 14, 2022

(54) CLASS-D AMPLIFIER, A METHOD OF CONTROLLING A GAIN OF AN INPUT AUDIO SIGNAL IN A CLASS-D AMPLIFIER

(71) Applicant: YAMAHA CORPORATION, Hamamatsu-shi (JP)

(72) Inventors: Shinya MIZOSHIRI, Hamamatsu-shi (JP); Masao NORO, Hamamatsu-shi (JP)

(21) Appl. No.: 17/705,626

(22) Filed: Mar. 28, 2022

Related U.S. Application Data
(63) Continuation of application No. PCT/JP2020/037284, filed on Sep. 30, 2020.

(30) Foreign Application Priority Data
Sep. 30, 2019 (JP) 2019-180508

(51) Int. Cl. H03F 3/217; H03F 1/32

(52) U.S. Cl. CPC H03F 3/2175; H03F 2200/351; H03F 2200/03; H03F 1/3264

(57) ABSTRACT

A class-D amplifier includes: a gain control unit that amplifies an input audio signal in accordance with a compensation gain to generate an input signal Vin; and a pulse width modulator that generates a first pulse Vp whose pulse width changes according to the input signal Vin within a first input range A1 where a value of the generated input signal Vin is higher than a first boundary Vb1, and that generates a second pulse Vn whose pulse width changes according to the generated input signal Vin within a second input range A2. The gain control unit controls the compensation gain so that first inclination of an input/output characteristic of the class-D amplifier in a first section in which the pulse width modulator outputs both the first pulse Vp and the second pulse Vn and second inclination of the input/output characteristic in a second section other than the first section are similar to each other.

### CROSS REFERENCE TO RELATED APPLICATIONS

The present application is a continuation application of International Application No. PCT/JP2020/037284, filed Sep. 30, 2020, which claims a priority to Japanese Patent Application No. 2019-180508, filed Sep. 30, 2019. The contents of these applications are incorporated herein by reference in their entirety.

### TECHNICAL FIELD

The present application relates to a class-D amplifier and a method of controlling a gain of an input audio signal in a class-D amplifier for driving a load with a pulse that is pulse-width modulated based on an input signal.

### BACKGROUND INFORMATION

A class-D amplifier is known that generates a first pulse whose pulse width increases in response to a change in an input signal in a positive direction and a second pulse whose pulse width increases in response to a change in the input signal in a negative direction, and drives a load such as a speaker with the first and second pulses.

In a filterless class-D amplifier among class-D amplifiers of this type, in a small output region in which the level of an input signal is close to zero and an output power with respect to the load is small, the range of the input signal from which the first pulse is output and the range of the input signal from which the second pulse is output overlap each other.

In the small output region, the input signal is falls between the lower limit of the input signal for generating the first pulse and the upper limit of the input signal for generating the second pulse. For this reason, in the small output region, both the pulse width of the first pulse and the pulse width of the second pulse are short. Therefore, the power consumption in the small output region is reduced.

### CITATION LIST

### Patent Literature

Patent Literature 1: JP 2018-137548A

### SUMMARY

In the above-described conventional class-D amplifier, in the small output region, a first pulse whose pulse width increases and a second pulse whose pulse width decreases in accordance with, for example, a change in the positive direction of the input signal are output. For this reason, inclination of input/output characteristic of the class-D amplifier is different between the small output region and the region other than the small output region, and there is the problem of the total harmonic distortion factor increasing.

A technique for preventing distortion of an output signal of a class-D amplifier is disclosed in, for example, Patent Document 1. In the technique disclosed in Patent Document 1, an offset voltage that generates distortion that cancels distortion generated by an output stage in a class-D amplifier is applied to an input signal of a pulse width modulator of the class-D amplifier.

However, even if such offset adjustment is performed, the voltage difference between the input signal (input signal to which the offset voltage is added) supplied to the pulse width modulator of the class-D amplifier and the carrier wave changes, and the pulse width of each pulse output from the pulse width modulator is only uniformly corrected. In the above-described conventional class-D amplifier, inclination of the input/output characteristic in the small output region is different from inclination of the input/output characteristic in the other region, and thus distortion occurs. For this reason, even if the offset is adjusted, the occurrence of distortion in the class-D amplifier is not suppressed.

The present disclosure has been made in view of the above-described circumstances, and provides a class-D amplifier and a method of controlling a gain of an input audio signal in a class-D amplifier that reduces power consumption in a small output region, and in which the total harmonic distortion factor does not increase.

The present disclosure provides a class-D amplifier including: a gain control unit configured to amplify an input audio signal in accordance with a compensation gain to generate an input signal; and a pulse width modulator configured to generate a first pulse whose pulse width changes according to the generated input signal within a first input range where a value of the generated input signal is higher than a first boundary, and a second pulse whose pulse width changes according to generated the input signal within a second input range. The second input range is the range where a value of the generated input signal is lower than a second boundary and partially overlapping the first input range. The gain control unit controls the compensation gain so that first inclination of an input/output characteristic of the class-D amplifier in a first section where the pulse width modulator outputs both the first pulse and the second pulse and second inclination of the input/output characteristic in a second section other than the first section are similar to each other.

The present disclosure provides a method of controlling a gain of an input audio signal in a class-D amplifier, the method comprising: amplifying the input audio signal in accordance with a compensation gain to generate an input signal; and generating a first pulse whose pulse width changes according to the generated input signal within a first input range where a value of the generated input signal is higher than a first boundary; generating a second pulse whose pulse width changes according to the generated input signal within a second input range where the value of the generated input signal is lower than a second boundary while partially overlapping the first input range; and wherein the amplifying controls the compensation gain so that inclination of an input/output characteristic of the class-D amplifier in a first section where the pulse width modulator outputs both the first pulse and the second pulse and inclination of the input/output characteristic in a second section other than the first section are similar to each other.

### BRIEF DESCRIPTION OF DRAWINGS

FIG. 1 is a block diagram of an example of a class-D amplifier according to an embodiment.

FIG. 2 shows waveform examples of an input signal of a pulse width modulator of the class-D amplifier and first and second pulses output from an output stage of the class-D amplifier.

FIG. 3 shows an example of an input/output characteristic of a section from the pulse width modulator to the output stage in the class-D amplifier.

FIG. 4 shows an example of an input/output characteristic of a section from a gain control unit to the output stage in the class-D amplifier.

FIG. 5 is a block diagram of an example of a class-D amplifier according to another embodiment.

FIG. 6 is a block diagram of an example of a class-D amplifier according to still another embodiment.

### DESCRIPTION OF EMBODIMENTS

Hereinafter, embodiments will be described with reference to the drawings.

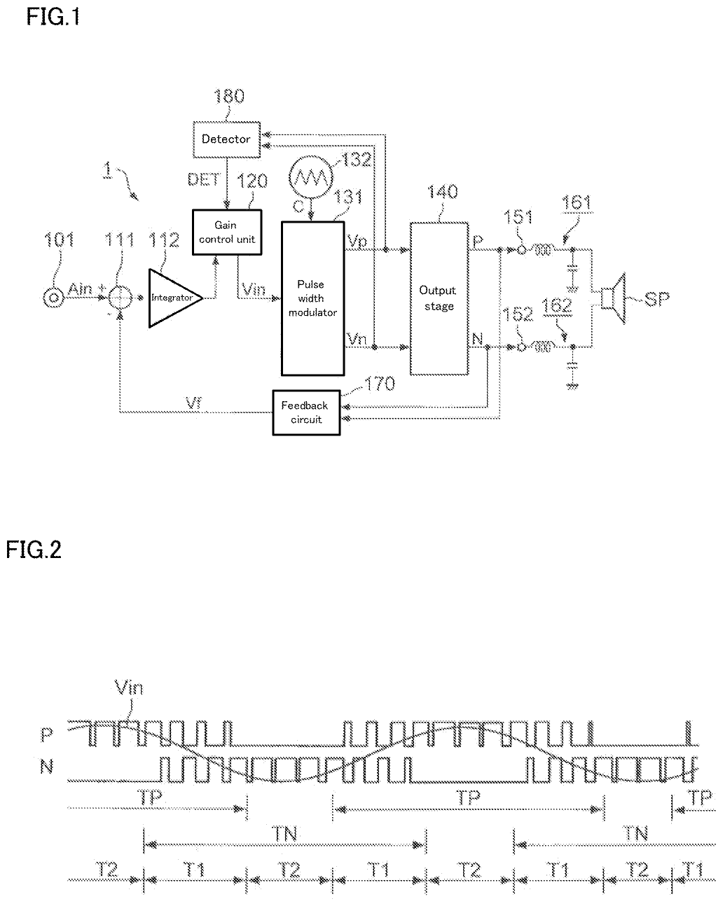

FIG. 1 is a block diagram of a class-D amplifier 1 according to an embodiment. In FIG. 1, LC filters 161 and 162 and a speaker SP serving as a load are shown together with the class-D amplifier 1 to facilitate understanding of the configuration of the class-D amplifier 1. The LC filters 161 and 162 are respectively connected to terminals 151 and 152 of the class-D amplifier 1. The speaker SP is connected between the LC filters 161 and 162. The LC filters 161 and 162 serve to remove the high-frequency component of the pulses output from the terminals 151 and 152.

In FIG. 1, a subtractor 111 subtracts a feedback signal Vf output from a feedback circuit 170 from an input audio signal Ain supplied via an input terminal 101, and outputs a signal indicating the subtraction result. An analog signal Ain varies within a voltage range from a maximum value A to a minimum value −A. An integrator 112 integrates and outputs an output signal of the subtractor 111. The output signal from the integrator 112 is supplied as an input signal Vin to a pulse width modulator 131 via a gain control unit 120.

A carrier wave generator 132 is a circuit that generates a periodic carrier wave C. The carrier wave C in the present embodiment is a triangular wave in which a rising section with a constant gradient and a falling section with a constant gradient are alternately repeated.

The pulse width modulator 131 outputs pulses Vp and Vn that are pulse-width modulated according to the input signal Vin based on the input signal Vin and the carrier wave C. More specifically, the pulse width modulator 131 compares a signal C+Vofs obtained by adding a positive offset voltage +Vofs to the carrier wave C with the input signal Vin, and compares a signal C−Vofs obtained by adding a negative offset voltage −Vofs to the carrier wave C with the input signal Vin. Then, the pulse width modulator 131 outputs the first pulse Vp and the second pulse Vn. The first pulse Vp is ON (H level or “1”) in a period in which the value (voltage) of the signal Vin is higher than the value (voltage) of the carrier wave C+Vofs, and Vos is otherwise OFF (L level or “0”). The second pulse Vn is ON (H level or “1”) in a period in which the value of the signal Vin is lower than the value of the carrier wave C−Vofs, and is otherwise OFF (L level or “0”). That is to say, the pulse width modulator 131 generates the first pulse Vp whose pulse width changes according to the input signal Vin within the first input range in which the value of the input signal Vin is larger than a first boundary Vb1 (=−A+Vofs). Also, the pulse width modulator 131 generates the second pulse Vn whose pulse width changes according to the input signal Vin within a second input range in which the value of the input signal Vin is smaller than a second boundary Vb2 (=+A−Vofs) and partially overlaps the first input range. Therefore, the pulse width modulator 131 has three states in total: a section (a positive second section) in which only the first pulse Vp changes according to the input signal Vin; a section (a first section) in which both the first pulse Vp and the second pulse Vn change; and a section (a negative second section) in which only the second pulse Vn changes according to the input signal Vin.

An output stage 140 amplifies the first pulse Vp and the second pulse Vn, and outputs the amplified pulses as a first pulse P and a second pulse N from the terminals 151 and 152 to the LC filters 161 and 162. The first pulse Vp and the first pulse P have the same shape. The second pulse Vn and the second pulse N have the same shape. The positive-side input of the speaker SP is supplied with a positive-side voltage of an audio signal obtained as a result of the LC filter 161 removing a high-frequency component from the first pulse P. The negative-side input of the speaker SP is supplied with a negative-side voltage of the audio signal obtained as a result of the LC filter 162 removing the high-frequency component from the second pulse N by. The feedback circuit 170 generates the above-described feedback signal Vf as a result of removing the high-frequency component of the first pulse P and the second pulse N, and supplies the feedback signal Vf to the subtractor 111. As a result of negatively feeding back the feedback signal Vf, the audio signal supplied to the speaker SP has a voltage waveform having substantially the same shape as the input audio signal Ain.

A detector 180 is a circuit that detects the state (at least one of the three states described above) of the pulse width modulator 131 according to the value of the input signal Vin. The detector 180 is, for example, a circuit that monitors the first pulse Vp and the second pulse Vn output from the pulse width modulator 131, and detects the first section in which both the first pulse Vp and the second pulse Vn are generated. The detector 180 sets a detection signal DET to the H level (or “1”) in the first section in which both the first pulse Vp and the second pulse Vn are generated, and sets the detection signal DET to the L level (or “0”) in a second section other than the first section.

In the first section, for example, when the input signal Vin changes in the positive direction, the pulse width modulator 131 outputs the first pulse Vp whose pulse width increases in accordance with the change in the positive direction and the second pulse Vn whose pulse width decreases in accordance with the change in the positive direction. First inclination of the input/output characteristic of the class-D amplifier 1 in the first section is twice as large as second inclination of the input/output characteristic of the class-D amplifier 1 in the positive second section in which only the first pulse Vp is output, or in the negative second section in which only the second pulse Vn is output. For this reason, unless some sort of measure is taken, second inclination of the input/output characteristic of the class-D amplifier 1 in the second section becomes half of first inclination of the input/output characteristic in the first section, and the input/output characteristic of the class-D amplifier 1 becomes nonlinear. As a result, the total harmonic distortion factor is higher than that in the case where inclination of the input/output characteristic is linear in all sections.

Accordingly, in the present embodiment, the pulse width modulator 131 and the gain control unit 120 are connected in series in the section between the input terminal 101 and the terminals 151 and 152. Specifically, the gain control unit 120 is provided in a preceding stage of the pulse width modulator 131.

The gain control unit 120 is configured to compensate for a nonlinear input/output characteristic of the class-D amplifier 1 to make it linear. On the basis of the detection signal DET, for example, the gain control unit 120 is a circuit that performs control such that first of the input/output characteristic of the class-D amplifier 1 in the first section and second inclination of the input/output characteristic of the class-D amplifier 1 in the second section other than the first section are similar to each other or become the same. Specifically, the gain control unit 120 sets the gain (inclination of the input/output characteristic) of the gain control unit 120 when the detection signal DET is at the L level to be twice as large as the gain of the gain control unit 120 when the detection signal DET is at the H level.

The configuration of the class-D amplifier 1 has been described above.

Next, operations of the present embodiment will be described. In the present embodiment, the duty ratio of the first pulse P and the duty ratio of the second pulse N when there is no signal depend on the offset voltages ±Vofs. As the absolute values of the offset voltages ±Vofs increase, the two duty ratios decrease. In the present embodiment, by appropriately setting the offset voltages ±Vofs, the two duty ratios are each set to an appropriate duty ratio of less than 50%, for example, about 10%.

In the present embodiment, when an input audio signal Ain varying within a voltage range from the maximum value A to the minimum value −A is supplied to the input terminal 101, and then when an input signal Vin is supplied to the pulse width modulator 131, the first pulse P and the second pulse N that have been pulse-width modulated according to the input signal Vin are output from the terminals 151 and 152.

FIG. 2 is a waveform diagram illustrating the input signal Vin of the pulse width modulator 131 and the first pulse P and the second pulse N output from the output stage 140. In FIG. 2, the horizontal axis represents time and the vertical axis represents voltage. In the example shown in FIG. 2, the input signal Vin is sinusoidal, and has a level of zero volts in the middle between its positive and negative peaks.

In FIG. 2, to facilitate understanding of the relationship between the input signal Vin and the pulse width of each of the first pulse P and the second pulse N, the first pulse P is superimposed on the positive half region of the waveform of the input signal Vin, and the second pulse N is superimposed on the negative half region of the input signal Vin.

In the present embodiment, the first pulse P whose pulse width changes according to the input signal Vin is output within the first input range in which the value of the input signal Vin is higher than the first boundary Vb1 (=−A+Vofs). Also, the second pulse N whose pulse width changes according to the input signal Vin is output within the second input range in which the value of the input signal Vin is lower than the second boundary Vb2 (=+A−Vofs) and partially overlaps the first input range.

In FIG. 2, the first pulse P is output in a section TP in which the input signal Vin is higher than the first boundary Vb1, and the second pulse N is output in a section TN in which the input signal Vin is lower than the second boundary. In the present embodiment, because the first input range and the second input range overlap each other, there is a section in which the section TP and the section TN overlap each other, that is to say, there is a first section T1 in which both the first pulse P and the second pulse N are output and a second section T2 other than the first section T1.

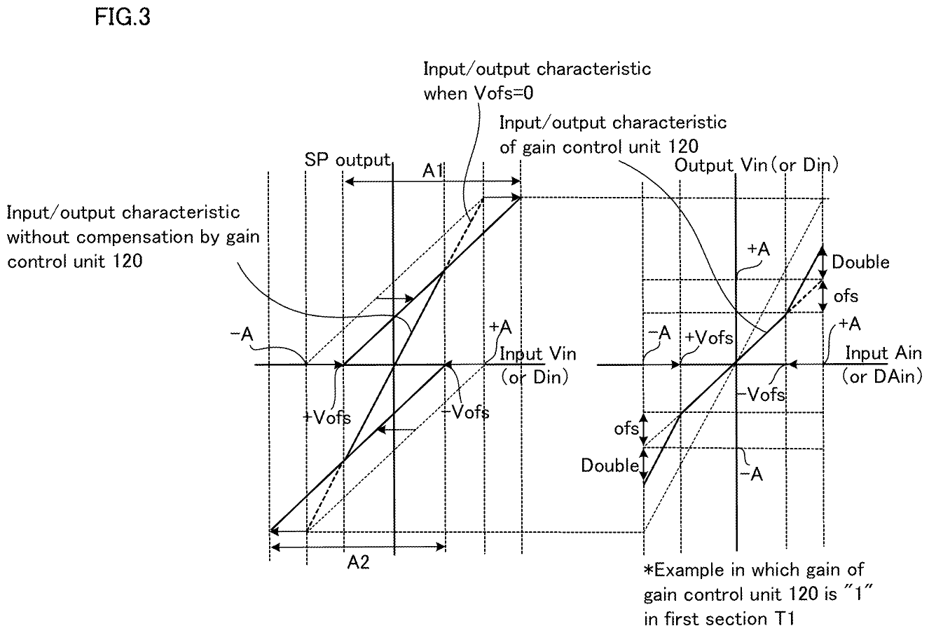

FIG. 3 shows the input/output characteristic of the section from the pulse width modulator 131 to the terminals 151 and 152. In FIG. 3, the horizontal axis represents input, that is to say, the value (voltage) of the input signal Vin, and the vertical axis represents output, that is to say, the pulse width of the first pulse P or the second pulse N, or the pulse width (time or duty ratio) of a pulse P-N obtained by combining the first pulse P and the second pulse N. In the present embodiment, as shown in FIG. 3, the duty ratio of the first pulse P and the duty ratio of the second pulse N when there is no signal (input signal Vin=0) are each smaller than 50%.

As shown in FIG. 3, in the first input range A1 in which the input signal Vin is higher than the first boundary Vb1 (=−A+Vofs), the pulse width of the first pulse P increases with a constant gain GP (inclination of the input/output characteristic) in accordance with the change in the input signal Vin in the positive direction. Also, in the second input range A2 in which the input signal Vin is lower than the second boundary Vb2 (=+A−Vofs), the pulse width of the second pulse N increases with a constant gain GN (inclination of the input/output characteristic) in accordance with the change in the input signal Vin in the negative direction. Here, because the first pulse P and the second pulse N are generated based on the common carrier wave C and have the same amplitude, the gain GP and the gain GN have the same value (Gpwm).

In FIG. 3, the first input range A1 and the second input range A2 overlap in an input range A3 having a lower limit −A+Vofs and an upper limit +A−Vofs. The section in which the input signal Vin is within the input range A3 is the first section T1 in which both the first pulse P and the second pulse N are output. In the pulse width modulator 131, the value of the gain G (inclination of the input/output characteristic) for the pulse P-N obtained by combining the first pulse P and the second pulse N is twice as large as the gains GP and GN of the first pulse P and the second pulse N alone (Gpwm×2).

Accordingly, unless some sort of measure is taken, second inclination of the input/output characteristic of the class-D amplifier 1 in the second section T2 (the gain in the second section T2) becomes half of the gain G in the first section T1, and the input/output characteristic becomes nonlinear, and thus the total harmonic distortion factor increases.

In the present embodiment, the gain control unit 120 provided in the preceding stage of the pulse width modulator 131 performs control to set the gain G2 of the gain control unit 120 in the second section T2 to be twice as large as the compensation gain G1 of the first section T1 (G1×2). Specifically, when the signal Ain is within the first section, the gain control unit 120 amplifies the signal Ain with the compensation gain G1, and outputs a signal Vin having a value of Ain×G1. When the signal Ain is within the positive second section, the gain control unit 120 amplifies the signal Ain with the compensation gain G2 that is twice as large as the compensation gain G1 (=G1×2), and outputs a signal Vin having a value of (Ain×2−Vb2)×G1. When the signal Ain is within the negative second section, the gain control unit 120 amplifies the signal Ain with the compensation gain G2 that is twice as large as the compensation gain G1, and outputs a signal Vin having a value of (Ain×2−Vb1)×G1. The analog circuit can be shared between the positive and negative second sections because only the boundaries that are used are different.

It is difficult to generate accurate analog values of the boundaries Vb1 and Vb2, and the boundaries Vb1 and Vb2 may vary depending on temperature, moisture, and the like. Accordingly, the signal Ain at the time of the signal Ain entering the second section from the first section may be sampled and held, and the held value Vh may be used as the boundaries Vb1 and Vb2. Specifically, when the signal Vin enters the positive second section from the first section, +A−Vofs is held as the value Vh, and when the signal Vin enters the negative second section from the first section, −A+Vofs is held as the value Vh. Then, when the signal Ain is within the second section, the gain control unit 120 outputs a signal Vin having a value of Vh×G1+(Ain−Vh)×2×G1=(Ain×2−Vh)×G1. The boundary to be used is automatically switched, and it is not necessary to distinguish whether the second section is the positive second section or the negative second section. The boundaries Vb1 and Vb2 obtained are highly accurate.

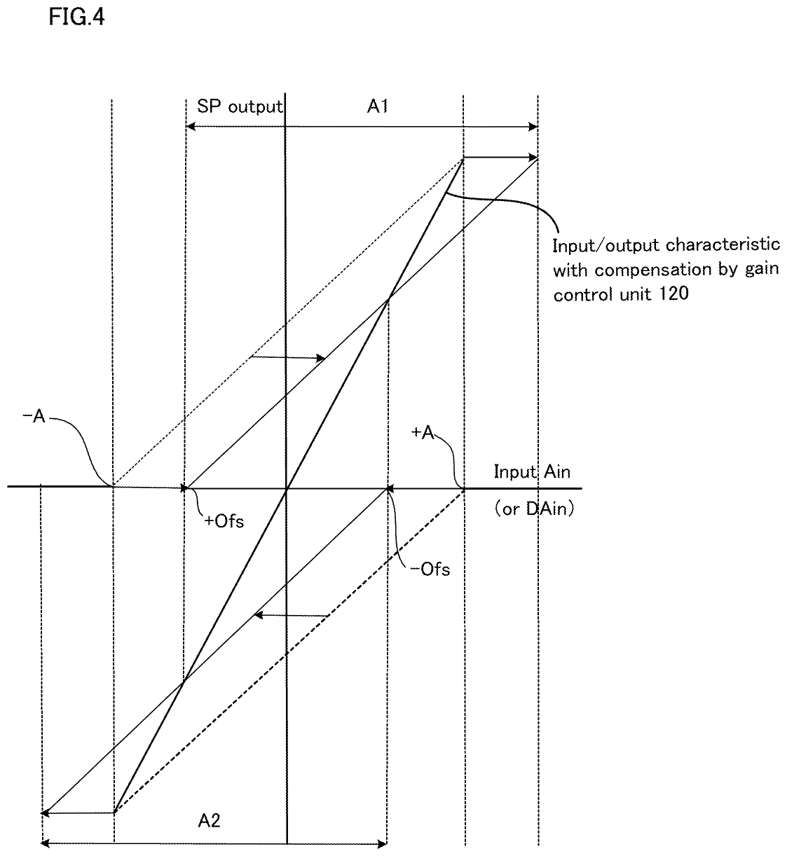

As a result, the input/output characteristic of the class-D amplifier 1 becomes linear as illustrated in FIG. 4. Even when the input signal Vin is within any of the input ranges A1, A2, and A3, the same gain G (=2×G1×Gpwm) is maintained. Therefore, the total harmonic distortion factor does not increase.

As described above, according to the present embodiment, the pulse width modulator 131 that generates the first pulse Vp whose pulse width changes according to the input signal Vin in the first input range A1 in which the value of the input signal Vin is higher than the first boundary Vb1 (=−A+Vofs), and that generates the second pulse Vn whose pulse width changes according to the input signal Vin in the second input range A2 in which the value of the input signal Vin is lower than the second boundary Vb2 (=+A−Vofs) and partially overlaps the first input range A1; and the gain control unit 120 that causes first inclination of the input/output characteristic in the first section T1 in which the pulse width modulator 131 outputs both the first pulse Vp and the second pulse Vn and second inclination of the input/output characteristic in the second section T2 other than the first section T1 to be similar to each other are provided. Therefore, the power consumption in the small output region can be reduced, and the total harmonic distortion factor can be suppressed.

Furthermore, according to the present embodiment, because the duty ratio of the first pulse P and the second pulse N when there is no signal is smaller than 50%, the power consumption of the class-D amplifier and the load when there is no signal is reduced. Accordingly, the class-D amplifier according to the present embodiment can achieve a quiet acoustic system in which the operation of an air-cooling fan is reduced. Furthermore, by using the class-D amplifier according to the present embodiment in a battery-driven acoustic system such as a powered speaker, the battery life of the acoustic system can be extended.

### Other Embodiments

While the embodiments have been described above, other embodiments are conceivable. Other embodiments are as follows, for example.

(1) The embodiments can be applied to a wide range of class-D amplifiers such as a class-D amplifier with a high output exceeding 100 W and a class-D amplifier with a low output installed in a cellular phone or the like. For a class-D amplifier with a low output, LC filters 161 and 162 may be omitted.

(2) In the above embodiment, the pulse width modulator 131 generates the pulse by comparing the input signal with a signal obtained by adding the offset voltage to the carrier wave. However, instead of this, the pulse may be generated by comparing the carrier wave with a signal obtained by adding the offset voltage to the input signal. Alternatively, the pulse may be generated by comparing a signal obtained by adding the offset signal and the carrier wave to the input signal with a threshold value.

(3) In the embodiment described above, the gain control unit 120 sets the gain of the gain control unit 120 in the second section T2 to be twice as large as the gain in the first section T1. However, instead of this, the gain of the gain control unit 120 in the first section T1 may be half as large as the gain in the second section T2. Also, instead of changing only the gain of one of the first section T1 and the second section T2 in this manner, the gain of both sections may be changed so that first inclination of the input/output characteristic in the first section T1 and second inclination of the input/output characteristic in the second section T2 are the same. In short, in the gain control unit 120, by changing at least one of the gain in the first section T1 and the gain in the second section T2 of the gain control unit 120 and setting the ratio of the two gains to 1:2, inclinations of the input/output characteristics of two sections of the class-D amplifier may be made the same.

(4) In the above-described embodiment, a triangular wave is used as a carrier wave for pulse-width modulation, but a carrier wave having a waveform other than a triangular wave, such as a sawtooth wave, may be used.

(5) In the above embodiment, the gain control unit 120 performs control such that first inclination of the input/output characteristic in the first section T1 is the same as second inclination of the input/output characteristic in the second section T2. However, inclinations of the input/output characteristics in the first section T1 and in the second section T2 may not strictly be the same. Even if inclinations of the input/output characteristics in the two sections are not exactly the same, if inclinations are made somewhat similar to each other, the total harmonic distortion factor is reduced by the amount they were made similar to each other.

(6) FIG. 5 is a block diagram illustrating a configuration of a class-D amplifier 1A according to another embodiment. In FIG. 5, the same components shown in FIG. 1 are denoted by the same reference numerals, and the description thereof will be omitted.

In the present embodiment, the detector 180 in the above embodiment is replaced with a detector 180A. The detector 180 in the above embodiment detects the low output section, based on the output state of the first pulse Vp and the second pulse Vn in the pulse width modulator 131. In contrast, the detector 180A detects the low output section by comparing the input audio signal Ain that is supplied from the input terminal 101 with first and second threshold values.

Specifically, the detector 180A sets the detection signal DET to the H level when the value of the input audio signal Ain is within the input range A3 in which both the first pulse Vp and the second pulse Vn are generated, that is to say, when the value of the input audio signal Ain is within the range from the first boundary Vb1 (=−A+Vofs) to the second boundary Vb2 (=+A−Vofs), and otherwise sets the detection signal DET to the L level. The operations of other units are the same as those of the above embodiment. Also in the present embodiment, the same effect as that of the above embodiment can be obtained.

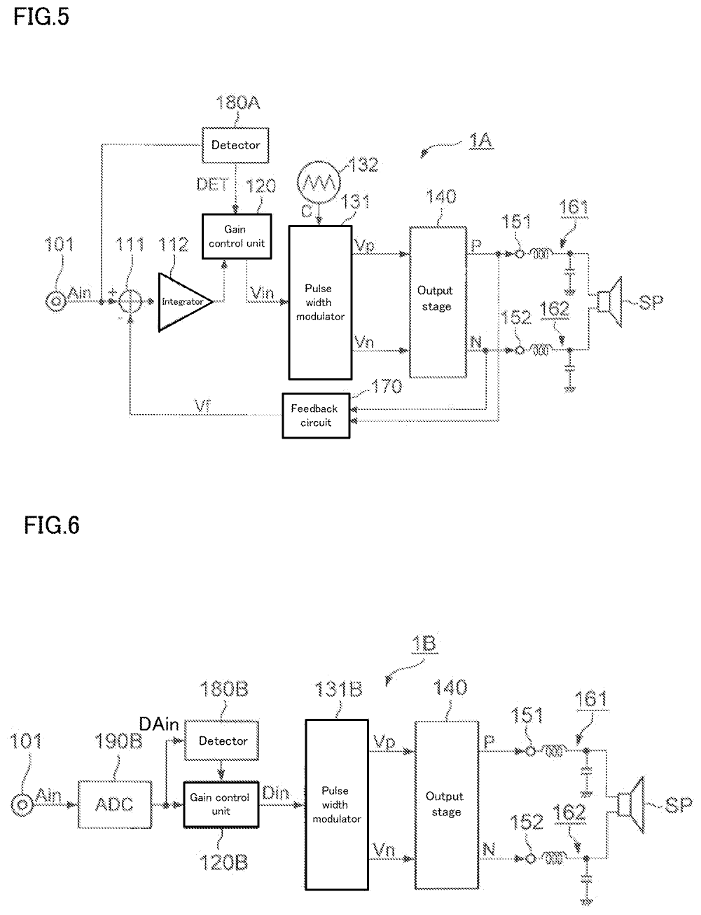

(7) FIG. 6 illustrates a configuration of a class-D amplifier 1B according to still another embodiment. Although pulse-width modulation is performed by the analog circuit in FIGS. 1 and 5, pulse-width modulation is performed by a digital circuit in this example. In FIG. 6, the same components shown in FIG. 1 are denoted by the same reference numerals, and the description thereof will be omitted.

The class-D amplifier 1B is provided with an ADC (Analogue Digital Converter) 190B that performs A/D conversion on the input analog signal Ain. The class-D amplifier 1B does not include components corresponding to the subtractor 111, the integrator 112, the carrier wave generator 132, and the feedback circuit 170 of the above embodiment (FIG. 1). Furthermore, in the class-D amplifier 1B, the gain control unit 120, the pulse width modulator 131, and the detector 180 of the above embodiment (FIG. 1) are replaced with a gain control unit 120B, a pulse width modulator 131B, and a detector 180B. The output stage 140 is similar to that of the above embodiment.

In the class-D amplifier 1B, the gain control unit 120B, the pulse width modulator 131B, the detector 180B, and the output stage 140 may be digital circuits, or may be functions realized by a processor such as a DSP (Digital Signal Processor) executing a program.

In FIG. 6, the detector 180B detects whether or not the value of a digital output signal DAin of the ADC 190B belongs to the input range A3 (from Vb1=−A+Vofs to Vb2=+A−Vofs) of the above embodiment (whether or not the value of DAin is within the first section T1), and supplies the detection signal DET that becomes the H level in the first section to the gain control unit 120B. As in the above embodiment, the gain control unit 120B amplifies the digital output signal DAin of the ADC 190B, so that the compensation gain G2 in the second section in which the detection signal DET is at the L level is twice (G1×2) as large as the compensation gain G1 in the first section in which the detection signal DET is at the H level, and supplies the amplified signal to the pulse width modulator 131B as the input signal Din. Specifically, the gain control unit 120B amplifies the input signal DAin in the first section with first inclination of the compensation gain G1 (DAin×G1), and amplifies the input signal DAin in the second section with second inclination of the compensation gain G2 (=2×G1). More specifically, the value of the amplified signal in the first section is 2×DAin×G1. The value of the amplified signal in the second section is (2×DAin−Vb2)×G1, when the signal DAin is positive. In contrast, the value of the amplified signal in the second section is (2×DAin−Vb1)×G1, when the signal DAin is negative. Furthermore, the pulse width modulator 131B generates a first pulse Vp and a second pulse Vn that are pulse-width modulated, based on the input signal Din supplied from the ADC 190B.

Specifically, the pulse width modulator 131B generates the first pulse Vp that is at the H level when the value of the digital input signal Din is larger than the value obtained by adding the offset value +Vofs to the value corresponding to the carrier wave C (triangular wave) of the above embodiment (FIG. 1), and that otherwise is at the L level. The pulse width modulator 131B generates the second pulse Vn that is at the H level when the value of the input signal Din2 is smaller than the value obtained by adding the offset voltage −Vofs to the value corresponding to the carrier wave C, and that otherwise is at the L level. The operations of the gain control unit 120B and other units are basically the same as those of the above embodiments. Also in the present embodiment, the same effect as that of the above embodiment can be obtained. If the gain control unit 120B and the detector 180B shown in FIG. 6 are replaced with a conversion table for non-linearly converting the value of the signal DAin into the value of the signal Din using the conversion characteristics shown in FIG. 4, the same effect as in the above embodiment can be obtained. In the present embodiment, the function of the detector 180B for determining whether or not the input signal DAin is within the first section is unnecessary.

1. A class-D amplifier comprising:
a gain control unit configured to amplify an input audio signal in accordance with a compensation gain to generate an input signal; and
a pulse width modulator configured to generate:
a first pulse whose pulse width changes according to the generated input signal within a first input range where a value of the generated input signal is higher than a first boundary; and
a second pulse whose pulse width changes according to the generated input signal within a second input range,
the second input range is the range where value of the generated input signal is lower than a second boundary and partially overlapping the first input range,
wherein the gain control unit controls the compensation gain so that first inclination of an input/output characteristic of the class-D amplifier in a first section where the pulse width modulator outputs both the first pulse and the second pulse and second inclination of the input/output characteristic in a second section other than the first section are similar to each other.

2. The class-D amplifier according to claim 1, wherein the compensation gain in the second section is twice as large as the compensation gain in the first section.

3. The class-D amplifier according to claim 2, further comprising:
a detector configured to detect the first section or the second section,
wherein the gain control unit holds a value of the input audio signal at a time point when the detector detects that the input audio signal has entered the second section from the first section, and the gain control unit uses the held value as the first boundary or the second boundary to control the compensation gain.

4. The class-D amplifier according to claim 1, wherein the detector detects the first section or the second section based on the first pulse and the second pulse.

5. The class-D amplifier according to claim 1, wherein the detector detects the first section or the second section based on the generated input signal.

6. The class-D amplifier according to claim 1, wherein, in a state where the level of the generated input signal is zero, the duty ratio of the first pulse and the duty ratio of the second pulse are each less than 50%.

7. The class-D amplifier according to claim 2, wherein, in a state where the level of the generated input signal is zero, the duty ratio of the first pulse and the duty ratio of the second pulse are each less than 50%.

8. The class-D amplifier according to claim 3, wherein, in a state where the level of the generated input signal is zero, the duty ratio of the first pulse and the duty ratio of the second pulse are each less than 50%.

9. The class-D amplifier according to claim 4, wherein, in a state where the level of the generated input signal is zero, the duty ratio of the first pulse and the duty ratio of the second pulse are each less than 50%.

10. The class-D amplifier according to claim 5, wherein, in a state where the level of the generated input signal is zero, the duty ratio of the first pulse and the duty ratio of the second pulse are each less than 50%.

11. A method of controlling a gain of an input audio signal in a class-D amplifier, the method comprising:
amplifying the input audio signal in accordance with a compensation gain to generate an input signal; and
generating a first pulse whose pulse width changes according to the generated input signal within a first input range where a value of the generated input signal is higher than a first boundary;
generating a second pulse whose pulse width changes according to the generated input signal within a second input range where the value of the generated input signal is lower than a second boundary while partially overlapping the first input range; and
wherein the amplifying controls the compensation gain so that inclination of an input/output characteristic of the class-D amplifier in a first section where the pulse width modulator outputs both the first pulse and the second pulse and inclination of the input/output characteristic in a second section other than the first section are similar to each other.
